(19) United States
(12) Patent Application Publication
(10) Pub. No.: US 2017/0154785 A1
(43) Pub. Date: Jun. 1, 2017

(54) METHOD FOR MANUFACTURING SEMICONDUCTOR DEVICE AND SEMICONDUCTOR DEVICE MANUFACTURING APPARATUS

(71) Applicant: KABUSHIKI KAISHA TOSHIBA, Tokyo (JP)

(72) Inventors: Yasuhito YOSHIMIZU, Yokkaichi (JP); Hiroyasu llMORI, Mie (JP); Katsuhiro SATO, Yokkaichi (JP)

(21) Appl. No.: 15/208,001

(22) Filed: Jul. 12, 2016

(30) Foreign Application Priority Data
Dec. 1, 2015 (JP) 2015-234997

(51) Int. Cl. H01L 21/311; C23F 1/16; H01L 21/67; H01L 27/115; H01L 21/02

(52) U.S. Cl. CPC H01L 21/31144; H01L 27/11582; H01L 21/0217; H01L 21/02164; H01L 21/31111; H01L 21/6708; C23F 1/16

(57) ABSTRACT

According to one embodiment, a method for manufacturing a semiconductor device includes the following processes. Second layers and first layers are alternately stacked on a substrate to form a stack. A mask layer is formed on the first layer in a surface of the stack. A part of the mask layer is removed to expose part of the first layer, and a protective layer is formed in a surface layer of the mask layer. The exposed first layer is etched with a first etching solution to expose part of the second layer after forming the protective layer. The exposed second layer is etched with a second etching solution after etching the first layer. The mask layer is etched with a third etching solution to further expose part of the first layer, after etching the first layer and etching the second layer.

### CROSS-REFERENCE TO RELATED APPLICATIONS

This application is based upon and claims the benefit of priority from prior Japanese Patent Application No. 2015-234997, filed Dec. 1, 2015, the entire contents of which are incorporated herein by reference.

### FIELD

Embodiments described herein relate generally to a method for manufacturing semiconductor device and a semiconductor device manufacturing apparatus.

### BACKGROUND

A nonvolatile semiconductor memory of a three-dimensional stacked type is known as a semiconductor device. In the nonvolatile semiconductor memory, memory cells are arranged in a three-dimensional manner on a semiconductor substrate. A manufacturing process of the memory includes a step of forming a stack formed by alternately stacking a plurality of conductive layers that function as control gates and a plurality of insulating layers, and forming the conductive layers of the stack in a step-like manner.

### BRIEF DESCRIPTION OF THE DRAWING

FIG. 1 is a diagram illustrating a structure of a memory cell array in a semiconductor device according to an embodiment;

FIG. 2 is a cross-sectional view of memory cells in the memory cell array according to the embodiment;

FIG. 3 is a cross-sectional view illustrating a step-like pattern in the semiconductor device according to the embodiment;

FIGS. 4 to 17 are cross-sectional views illustrating a method for manufacturing the step-like pattern in the semiconductor device according to the embodiment;

FIG. 18 is a diagram illustrating a relation between first layers, second layers, a mask layer, and etching solutions according to other embodiments;

FIG. 19 is a flowchart illustrating a process of etching a wafer on which the semiconductor device according to the embodiment is formed;

FIG. 20 is a flowchart illustrating a process of etching a wafer on which a semiconductor device of a comparative example is formed;

FIG. 21 is a diagram illustrating an example of a manufacturing apparatus for the semiconductor device according to the embodiment; and

FIGS. 22 and 23 are diagrams illustrating other examples of the manufacturing apparatus for the semiconductor device according to the embodiment.

### DETAILED DESCRIPTION

In general, according to one embodiment, a method for manufacturing a semiconductor device includes alternately stacking second layers and first layers on a substrate to form a stack; forming a mask layer on the first layer in a surface of the stack; removing part of the mask layer to expose part of the first layer, and forming a protective layer in a surface layer of the mask layer; etching the exposed first layer with a first etching solution, to expose part of the second layer, after forming the protective layer; etching the exposed second layer with a second etching solution, after etching the first layer, and; etching the mask layer with a third etching solution, to further expose the first layer, after etching the first layer and etching the second layer.

An embodiment will be explained hereinafter with reference to the drawings. In the following explanation, constituent elements having the same function and structure will be denoted by the same reference numerals. This explanation illustrates an example of a three-dimensional stacked nonvolatile semiconductor memory in which memory cell transistors are arranged in a three-dimensional manner on a semiconductor substrate, as the semiconductor device.

### [1] Embodiment

Before explanation of a method for manufacturing the semiconductor device according to the embodiment, the whole structure of the semiconductor device will be explained.

### [1-1] Whole Structure of Semiconductor Device

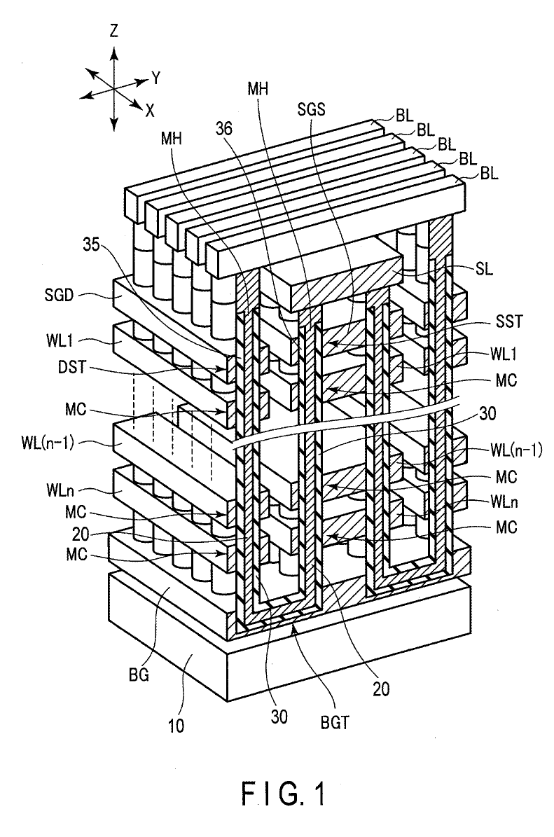

FIG. 1 is a diagram illustrating a structure of a memory cell array of the semiconductor device according to the embodiment. In FIG. 1, to clarify the drawing, illustration of insulating portions other than the insulating film formed in a memory hole MH is omitted. The following embodiment illustrates silicon as a semiconductor, but semiconductors other than silicon may be used.

In the present embodiment, an XYZ orthogonal coordinate system is introduced for convenience of explanation. In the coordinate system, two directions that are orthogonal to each other and parallel with the principal plane of the substrate 10 serve as an X direction and a Y direction, and a direction orthogonal to both the X direction and the Y direction serves as a Z direction. A plurality of conductive layers WL1, WL2, . . . , WL (n+1), and WLn are stacked in the Z direction. The symbol n denotes a natural number of 1 or more. In the following explanation, the term “conductive layer WL” indicates each of the layers WL1, WL2, . . . , WL (n+1), and WLn.

A back gate BG is provided on the substrate 10 with an insulating layer (not illustrated) interposed therebetween. The back gate BG is, for example, a conductive silicon layer including added impurities. The conductive layers WL1 to WLn and insulating layers (not illustrated) are alternately stacked on the back gate BG. The conductive layers WL1 to WLn are, for example, conductive silicon layers including added impurities.

Each of the conductive layers WL1 to WLn is divided into a plurality of blocks with slits extending in the X direction. A drain selection gate SGD is provided on the uppermost conductive layer WL1 in a block, with an insulating layer (not illustrated) interposed therebetween. The drain selection gate SGD is, for example, a conductive silicon layer including added impurities. A source selection gate SGS is provided, with an insulating layer (not illustrated) interposed therebetween, on the uppermost conductive layer WL1 in another block adjacent to the block. The source selection gate SGS is, for example, a conductive silicon layer including added impurities.

A source line SL is provided on the source selection gate SGS, with an insulating layer (not illustrated) interposed therebetween. The source line SL is, for example, a conductive silicon layer including added impurities. A metal material may be used as the source line SL. A plurality of bit lines BL are provided on the source line SL and the drain selection gate SGD, with an insulating layer (not illustrated) interposed therebetween. Each of the bit lines BL extends in the Y direction.

The stack described above on the substrate 10 is provided with a plurality of U-shaped memory holes MH. The block including the drain selection gate SGD is provided with a memory hole that runs through the drain selection gate SGD and the conductive layers WL1 to WLn located under the gate and extends in the Z direction. The block including the source selection gate SGS is provided with a memory hole that runs through the source selection gate SGS and the conductive layers WL1 to WLn located under the gate and extends in the Z direction. Both the memory holes are connected via a memory hole formed in the back gate BG and extending in the Y direction.

The inside of the memory holes MH is provided with a silicon body 20 serving as a U-shaped semiconductor layer. A gate insulating film 35 is formed on an internal wall of the memory hole between the drain selection gate SGD and the silicon body 20. A gate insulating film 36 is formed on an internal wall of the memory hole between the source selection gate SGS and the silicon body 20. An insulating film 30 is formed on an internal wall of the memory hole between the conductive layers WL1 to WLn and the silicon body 20. The insulating film 30 is formed also on an internal wall of the memory hole between the back gate BG and the silicon body 20. The insulating film 30 has an ONO (Oxide-Nitride-Oxide) structure in which a silicon nitride film is held between a pair of silicon oxide films.

### [1-2] Structure of Memory Cells

The following is explanation of the structure of the memory cells in the memory cell array. The present embodiment illustrates, for example, the case of including four conductive layers.

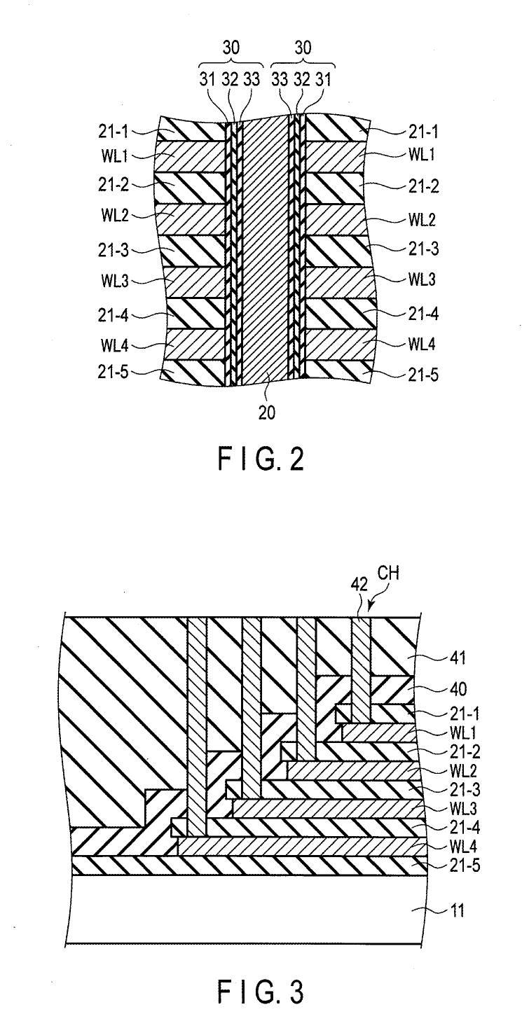

FIG. 2 is a cross-sectional view of a portion of the memory cell array, in which the silicon body 20 extends through the conductive layers WL1 to WL4 and insulating layers 21_1, 21_2, 21_3, and 21_4 between the conductive layers.

A first insulating film 31, a charge storage layer 32, and a second insulating film 33 are provided in this order from the conductive layers WL1 to WL4 side, between the conductive layers WL1 to WL4 and the silicon body 20. The first insulating film 31 contacts the conductive layers WL1 to WL4, the second insulating film 33 contacts the silicon body 20, and the charge storage layer 32 is provided between the first insulating film 31 and the second insulating film 33.

The silicon body 20 functions as a channel, the conductive layers WL1 to WL4 function as control gates, and the charge storage layer 32 functions as a data storage layer that stores charges injected from the silicon body 20. Specifically, memory cells are formed in respective portions in which the silicon body 20 crosses each of the conductive layers WL1 to WL4. The memory cells have a structure in which control gates surround the channel.

The semiconductor device according to the present embodiment is a nonvolatile semiconductor storage device that is capable of electrically erasing and writing data without constraint, and holding the stored contents even when the power is turned off. For example, the memory cells are memory cells having a charge-trap structure.

The charge storage layer 32 includes a number of traps to confine charges (electrons), and is formed of, for example, a silicon nitride film. The second insulating film 33 is formed of, for example, a silicon oxide film, and serves as a potential barrier when charges are injected from the silicon body 20 into the charge storage layer 32, or when the charges stored in the charge storage layer 32 are diffused into the silicon body 20. The first insulating film 31 is formed of, for example, a silicon oxide film, and prevents the charges stored in the charge storage layer 32 from being diffused into the conductive layers WL1 to WL4.

The following explanation is made with reference to FIG. 1 again. The gate insulating film 35 is provided between the silicon body 20 running through the drain selection gate SGD and the drain selection gate SGD. The drain selection gate SGD, the silicon body 20, and the gate insulating film 35 form a drain selection transistor DST. Upper end portions of the silicon body 20 above the drain selection gate SGD are connected to respective corresponding bit lines BL.

The gate insulating film 36 is provided between the silicon body 20 running through the source selection gate SGS and the source selection gate SGS. The source selection gate SGS, the silicon body 20, and the gate insulating film 36 form a source selection transistor SST. Upper end portions of the silicon body 20 above the source selection gate SGS are connected to the source line SL.

The back gate BG, the silicon body 20 provided in the back gate BG, and the insulating film 30 between the back gate BG and the silicon body 20 form a back gate transistor BGT.

A memory cell MC1 including the conductive layer WL1 as a control gate, a memory cell MC2 including the conductive layer WL2 as a control gate, a memory cell MC3 including the conductive layer WL3 as a control gate, and a memory cell MC4 including the conductive layer WL4 as a control gate are provided between the drain selection transistor DST and the back gate transistor BGT.

A memory cell MC5 including the conductive layer WL4 as a control gate, a memory cell MC6 including the conductive layer WL3 as a control gate, a memory cell MC7 including the conductive layer WL2 as a control gate, and a memory cell MC8 including the conductive layer WL1 as a control gate are provided between the back gate transistor BGT and the source selection transistor SST.

The drain selection transistor DST, the memory cells MC1 to MC4, the back gate transistor BGT, the memory cells MC5 to MC8 and the source selection transistor SST are connected in series, to form a memory string. A plurality of memory strings having such a structure are arranged in the X direction and the Y direction, and thereby the memory cells MC1 to MC8 are provided in a three-dimensional manner in the X direction, the Y direction, and the Z direction.

### [1-3] Structure of Contact Region (Step-Like Pattern)

FIG. 3 illustrates a cross-sectional structure of a contact region to electrically connect the conductive layers WL1 to WL4 with respective upper-layer interconnects (not illustrated). The contact region has step-like patterns of the conductive layers. The contact region is a region outside the region in which the memory cell array illustrated in FIG. 1 is formed in the X direction

Part of the stack including the conductive layers WL1 to WL4 and the insulating layers 21_1, 21_2, . . . , and 21-5 is processed in a step-like manner with the contact region. The step-like pattern (stepwise structure portion) is covered with a stopper layer 40, and an interlayer insulating layer 41 is provided on the stopper layer 40. For example, the stopper layer 40 is a silicon nitride, and the interlayer insulating layer 41 is a silicon oxide. In the following explanation, the term “insulating layer 21” indicates each of the insulating layers 21_1, 21_2, . . . , and 21_5.

A plurality of contact holes CH are formed in the interlayer insulating layer 41 and the stopper layer 40, and contact electrodes 42 are provided in the respective contact holes CH.

The contact holes CH run through the interlayer insulating layer 41, the stopper layer 40, and the respective insulating layers 21_1 to 21_4, and reach the respective corresponding conductive layers WL. For example, tungsten is embedded into each of the contact holes CH, as the contact electrode 42. The conductive layers WL1 to WL4 are connected to respective upper-layer interconnects via the respective contact electrodes 42.

### [1-4] Method for Manufacturing Semiconductor Device

The following is explanation of a method for forming a step-like pattern of the conductive layers WL and the insulating layers 21 in the present embodiment. The method illustrates an example of the case where silicon nitride layers serving as sacrificial layers are formed first instead of the conductive layers WL, thereafter the silicon nitride layers are removed, and conductive materials serving as conductive layers WL are formed in regions from which the silicon nitride layers have been removed. This explanation also illustrates the example of stacking four conductive layers WL1 to WL4, but the number of conductive layers may be any number.

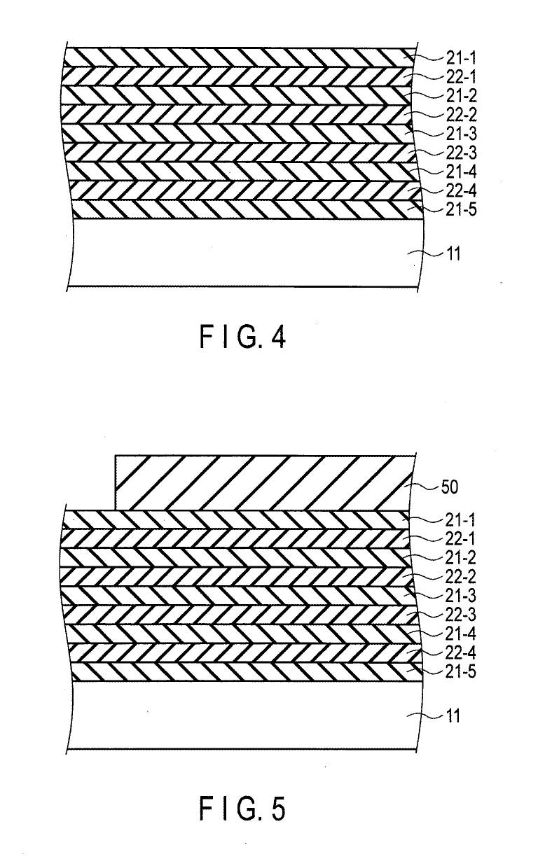

First, as illustrated in FIG. 4, a plurality of insulating layers (first layers) 21_1 to 21_5 and a plurality of sacrificial layers (second layers) 22_1, 22_2, 22_3, and 22_4 are alternately formed on a substrate 11, to form a stack thereof. In the following explanation, the term “sacrificial layer 22” indicates each of the sacrificial layers 22_1, 22_2, 22_3, and 22_4.

The substrate 11 includes the substrate 10 in FIG. 1, the back gate BG, insulating layers between the layers, and the like. In the back gate BG of the memory cell array region, a recessed portion corresponding to a bottom portion of the U-shaped memory string is formed before formation of the stack of the insulating layers 21 and the conductive layers WL. Then, a sacrificial layer that is different from the sacrificial layers 22 is embedded into the recessed portion, and thereafter the insulating layers 21 and the sacrificial layers 22 are stacked.

The insulating layers 21 are silicon oxide layers mainly including a silicon oxide, and the sacrificial layers 22 are, for example, silicon nitride layers. The insulating layers 21 and the sacrificial layers 22 are formed by, for example, CVD (chemical vapor deposition).

After formation of the stack obtained by stacking the insulating layers 21 and the sacrificial layers 22, the memory cell array region is subjected to a process of forming the memory cells MC, the drain selection transistor DST, the source selection transistor SST, and the back gate transistor BGT. The sacrificial layer embedded into the recessed portion of the back gate BG is removed through holes formed to run through the stack in the vertical direction (stacking direction). In this manner, the U-shaped memory holes MH are formed. The insulating film 30 including the charge storage layer 32 is formed on the internal wall of each of the memory holes MH, and the silicon body 20 serving as the channel is formed on the insulating film 30 in each of the memory holes.

After the memory cell array described above is formed, the following process is performed to form the step-like pattern.

First, a silicon layer 50 is formed on the stack. Specifically, as illustrated in FIG. 5, the silicon layer 50 is formed on the insulating layer 21_1. Thereafter, the silicon layer 50 is patterned by photolithography, to set an end portion of the silicon layer 50 to a desired position.

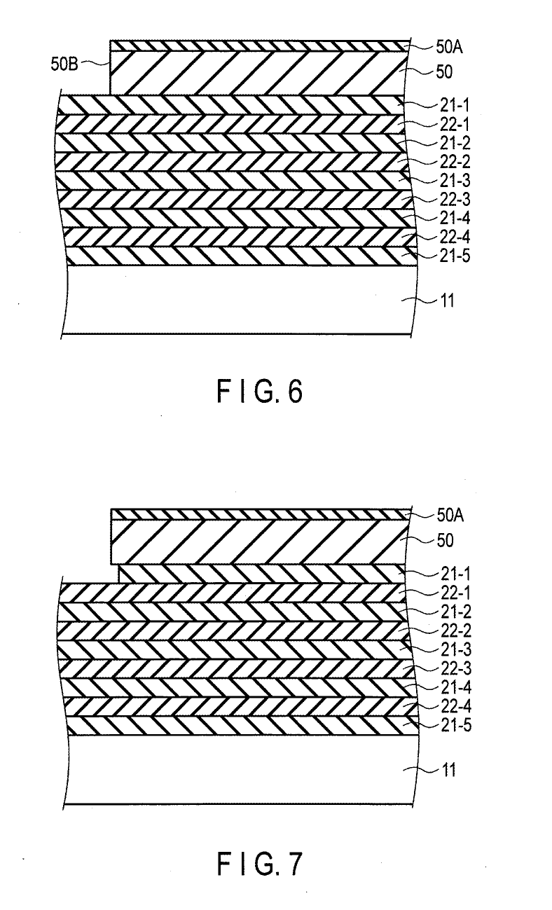

Next, impurities are implanted into a surface portion of the silicon layer 50 by ion implantation. In this manner, as illustrated in FIG. 6, a protective layer 50A is formed with an impurity concentration of 10¹⁸ cm⁻³ or more in the surface portion of the silicon layer 50. The impurities are, for example, p-type impurities (boron (B), aluminum (Al)), n-type impurities (phosphor (P), arsenic (As)), or carbon (C).

Specifically, the protective layer 50A is formed as follows.

In a treatment chamber, for example, a BCl₃ gas including boron (B) is introduced, and an electric power is applied to an upper antenna in the treatment chamber, to produce plasma in the treatment chamber. In this manner, B (boron) that is generated by decomposition of BCl₃ is implanted into the upper surface of the silicon layer 50. In the implantation, high-frequency power is applied to the substrate 11 side, and B is accelerated with directivity in the vertical direction toward the substrate 11 side, and implanted into the upper surface of the silicon layer 50.

Therefore, B is hardly implanted into a side surface 50B of the silicon layer 50, and little protective layer is formed on the side surface 50B of the silicon layer 50. No problem occurs even when B is implanted into the insulating layer 21_1 exposed from the silicon layer 50.

Thereafter, a first etching solution is supplied to the structure illustrated in FIG. 6, or the structure illustrated in FIG. 6 is immersed in the first etching solution to perform wet etching, to remove the insulating layer (for example, the silicon oxide layer) 21_1 as illustrated in FIG. 7. The first etching solution is, for example, hydrofluoric acid or a chemical solution including hydrofluoric acid.

In the etching, the etching rate of the first etching solution for the insulating layer 21_1 is higher than the etching rate of the first etching solution for the sacrificial layers 22 and the silicon layer 50. In other words, in the wet etching of the insulating layer 21_1, the sacrificial layers 22 and the silicon layer 50 with the first etching solution, the first etching solution has a sufficient etching selection ratio for the insulating layer 21_1. For this reason, the sacrificial layers 22 and the silicon layer 50 are not etched much, and only the insulating layer 21_1 is etched.

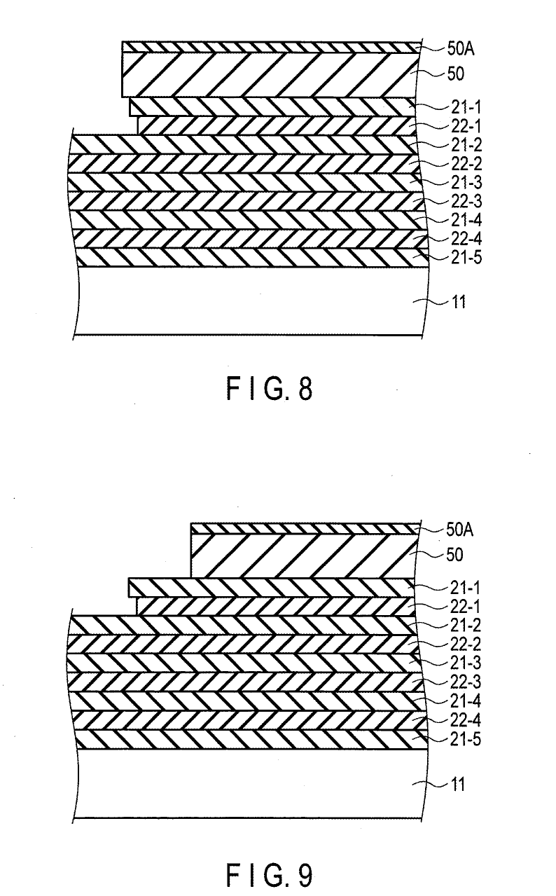

In addition, a second etching solution is supplied to the structure illustrated in FIG. 7, or the structure illustrated in FIG. 7 is immersed in the second etching solution to perform wet etching, to remove the sacrificial layer (for example, the silicon nitride layer) 22_1 as illustrated in FIG. 8. The second etching solution is, for example, hot phosphoric acid.

In the etching, the etching rate of the second etching solution for the sacrificial layer 22_1 is higher than the etching rate of the second etching solution for the insulating layers 21 and the silicon layer 50. In other words, in the wet etching of the insulating layers 21, the sacrificial layer 22_1 and the silicon layer 50 with the second etching solution, the second etching solution has a sufficient etching selection ratio for the sacrificial layer 22_1. For this reason, the insulating layers 21 and the silicon layer 50 are not etched much, and only the sacrificial layer 22_1 is etched.

Thereafter, a third etching solution is supplied to the structure illustrated in FIG. 8, or the structure illustrated in FIG. 8 is immersed in the third etching solution to perform wet etching, to remove the silicon layer 50 in the X and Y directions (plane direction), as illustrated in FIG. 9. In this manner, the insulating layer 21_1 is newly exposed. The third etching solution is, for example, an alkaline aqueous solution. The alkali used for the alkaline aqueous solution is, for example, inorganic alkali such as NaOH, KOH, and NH₄OH, or organic alkali such as TMAH and choline.

In the etching, the etching rate of the third etching solution for the silicon layer 50 is higher than the etching rate of the third etching solution for the insulating layers 21 and the sacrificial layers 22. In other words, in the wet etching of the insulating layers 21, the sacrificial layers 22 and the silicon layer 50 with the third etching solution, the third etching solution has a sufficient etching selection ratio for the silicon layer 50. For this reason, the insulating layers 21 and the sacrificial layers 22 are not etched much, and only the silicon layer 50 is etched.

The silicon layer 50 can be etched with an alkaline aqueous solution, but the silicon layer (protective layer 50A) with the impurity concentration of 10¹⁸ cm⁻³ or more has a characteristic of not dissolving with an alkaline aqueous solution. Specifically, by forming the protective layer 50A on the surface portion of the silicon layer 50, only the silicon layer 50 excepting the protective layer 50A is subjected to wet etching.

When the thickness of the protective layer 50A is large, the silicon layer 50 is removed in the X and Y directions by wet etching, and the protective layer 50A is left above the exposed insulating layer 21_1. Even when the protective layer 50A is left above the insulating layer 21_1 like this, no problem occurs in the subsequent process. However, when the thickness of the protective layer 50A is several nanometers or less, the protective layer 50A is also removed with high probability by wet etching, and therefore the thickness of the protective layer 50A is preferably several nanometers or more. FIG. 9 illustrates the case where the protective layer 50A above the exposed insulating layer 21_1 is removed by wet etching. The thickness of the protective layer 50A is, for example, 10 nm or less, and 1 nm or more.

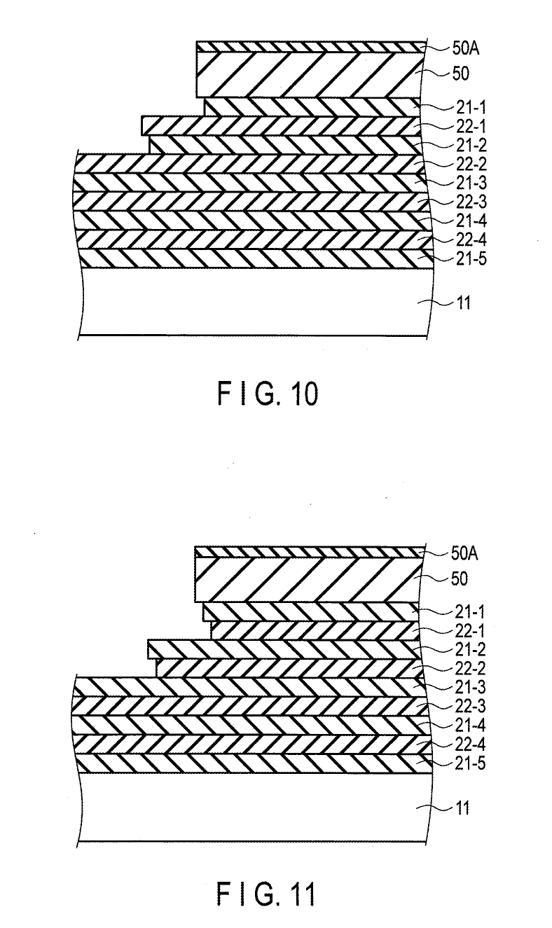

Next, the first etching solution is supplied to the structure illustrated in FIG. 9, or the structure illustrated in FIG. 9 is immersed in the first etching solution to perform wet etching, to remove the insulating layers 21_1 and 21_2 as illustrated in FIG. 10. In the etching, the etching rate and the etching selection ratio of the first etching solution for the structure are the same as those described above.

In addition, the second etching solution is supplied to the structure illustrated in FIG. 10, or the structure illustrated in FIG. 10 is immersed in the second etching solution to perform wet etching, to remove the sacrificial layers 22_1 and 22_2 as illustrated in FIG. 11. In the etching, the etching rate and the etching selection ratio of the second etching solution for the structure are the same as those described above.

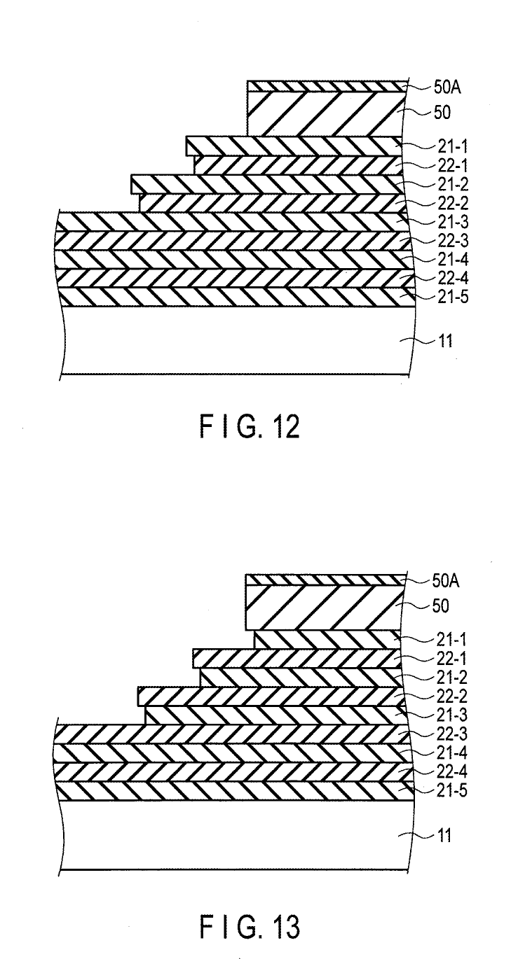

Thereafter, the third etching solution is supplied to the structure illustrated in FIG. 11, or the structure illustrated in FIG. 11 is immersed in the third etching solution to perform wet etching, to remove the silicon layer 50 in the X and Y directions as illustrated in FIG. 12. In this manner, the insulating layer 21_1 is newly exposed. In the etching, the etching rate and the etching selection ratio of the third etching solution for the structure are the same as those described above.

In addition, the first etching solution is supplied to the structure illustrated in FIG. 12, or the structure illustrated in FIG. 12 is immersed in the first etching solution to perform wet etching, to remove the insulating layers 21_1, 21_2, and 21_3 as illustrated in FIG. 13. In the etching, the etching rate and the etching selection ratio of the first etching solution for the structure are the same as those described above.

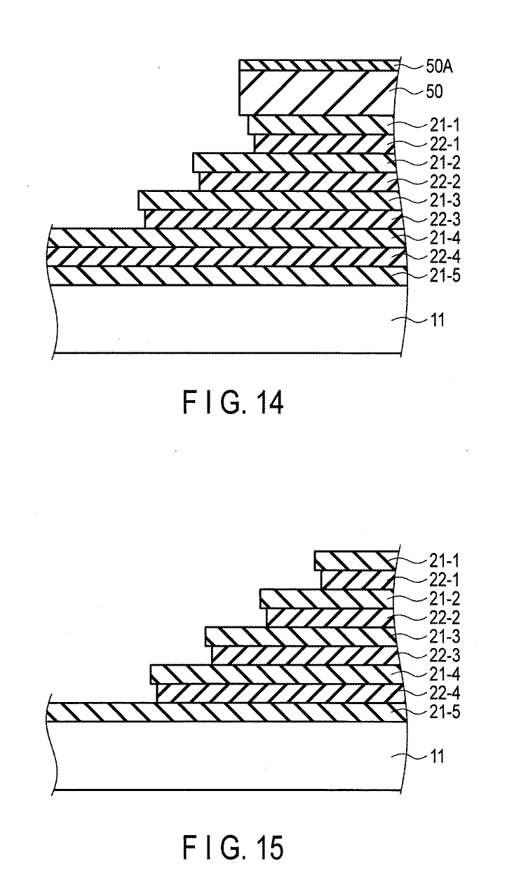

Thereafter, the second etching solution is supplied to the structure illustrated in FIG. 13, or the structure illustrated in FIG. 13 is immersed in the second etching solution to perform wet etching, to remove the sacrificial layers 22_1, 22_2, and 22_3 as illustrated in FIG. 14. In the etching, the etching rate and the etching selection ratio of the second etching solution for the structure are the same as those described above.

Three chemical solution treatments with the first etching solution (hydrofluoric acid), the second etching solution (hot phosphoric acid), and the third etching solution (alkaline aqueous solution) illustrated in FIG. 7 to FIG. 9, FIG. 10 to FIG. 12, or FIG. 13 to FIG. 15 are a cycle unit to form the step-like pattern. By repeating the cycle unit, the second step, the third step, and the fourth step of the step-like pattern are successively formed, as illustrated in FIG. 15. The process described above enables easy formation of the step-like pattern of the stacked films necessary for the semiconductor device. FIG. 15 illustrates a state where the silicon layer 50 is removed after the step-like pattern is formed.

Instead of ion-implanting impurities and forming the protective layer 50A, a dry etching damage layer formed in the surface portion of the silicon layer 50 is expected to produce the effect of protecting the silicon layer 50 from wet etching. However, because the damage layer may be pierced by repeated wet etching with an alkaline aqueous solution, the protective layer 50A is preferably formed by implantation of impurities used in the present embodiment.

In addition, because the wet etching used for removal of the insulating layer 21 and the sacrificial layer 22 is isotropic etching, the insulating layer 21 and the sacrificial layer 22 are etched also in the X and Y directions (plane direction). However, such etching does not cause any problem, because the plane direction (dimension) is sufficiently longer than the thickness direction (dimension) of the insulating layer 21 or the sacrificial layer 22. Specifically, the thickness of the insulating layer 21 or the sacrificial layer 22 is dozens of nanometers, while the length of the shelf portion of the step-like pattern is several hundred to one thousand nanometers. Accordingly, because the length of the shelf portion of the step-like pattern is 10 times to 100 times as large as the thickness of the insulating layer 21 or the sacrificial layer 22, the etching amount of the insulating layer 21 or the sacrificial layer 22 in the plane direction by wet etching can be ignored.

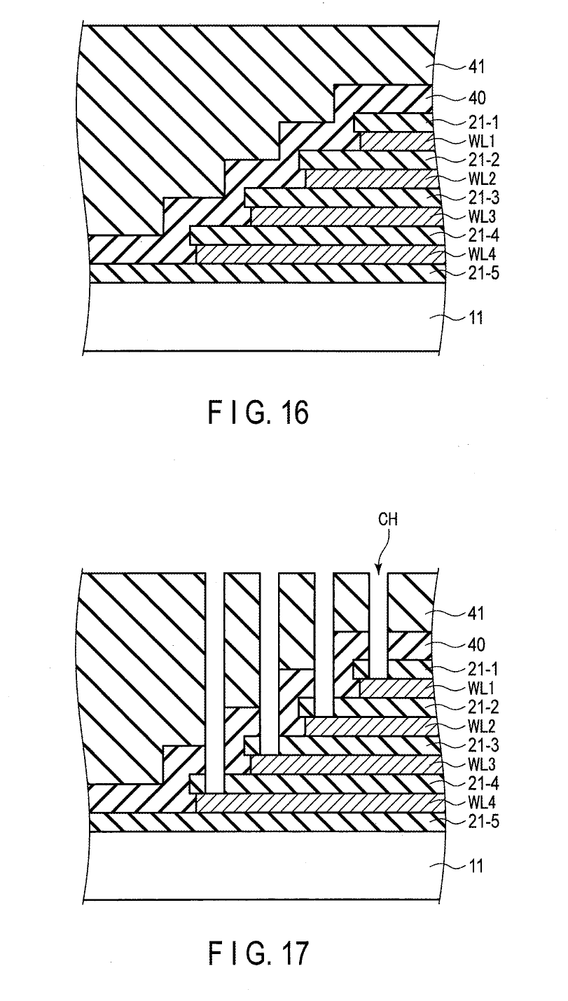

Thereafter, in the structure illustrated in FIG. 15, for example, the sacrificial layers 22_1 to 22_4 are removed with hot phosphoric acid. Then, a conductive material (such as metal layers) is embedded into the regions where the sacrificial layers 22_1 to 22_4 existed, to form the conductive layers WL1 to WL4 as illustrated in FIG. 16.

Next, a stopper 40 is formed to cover the step-like pattern of the insulating layers 21 and the conductive layers WL. The stopper 40 is, for example, a silicon nitride layer. In addition, an interlayer insulating layer 41 is formed on the stopper 40. For example, the interlayer insulating layer 41 is formed of a material different from the stopper 40, such as a silicon oxide layer.

Thereafter, after the upper surface of the interlayer insulating layer 41 is flattened, a mask layer (not illustrated) is formed on the interlayer insulating layer 41, and the interlayer insulating layer 41, the stopper 40, and the insulating layers 21_1 to 21_4 on the conductive layer WL1 to WL4 are etched using the mask layer. In this manner, as illustrated in FIG. 17, contact holes CH are formed in the interlayer insulating layer 41, the stopper 40, and the respective insulating layers 21_1 to 21_4. The contact holes CH have mutually different depths from the upper surface of the interlayer insulating layer 41. The contact holes CH run through the interlayer insulating layer 41, the stopper 40, and the respective corresponding insulating layers 21, and reach the respective corresponding conductive layers WL.

The contact holes CH are simultaneously formed together by RIE (Reactive Ion Etching). By processing the conductive layers WL1 to WL4 in a step-like manner, the contact holes CH reaching the respective conductive layers WL can be efficiently formed together with the same etching process. In the process, the stopper layer 40 being a silicon nitride layer functions as an etching stopper when the interlayer insulating layer 41 being a silicon oxide layer is etched.

After the contact holes CH are formed, contact electrodes 42 are formed therein as illustrated in FIG. 3. Specifically, first, a first barrier film (such as a titanium film) is formed on the internal wall of each of the contact holes CH, a second barrier film (such as a titanium nitride film) is formed inside the first barrier film, and a conductive material with excellent embeddability, such as tungsten (W), is embedded inside the second barrier film. The first and second barrier films prevent diffusion of tungsten. The first and second barrier films also function as contact layers in close contact with both the internal wall of the contact hole CH and tungsten.

### [1-5] Effects of Embodiment

The present embodiment enables easy formation of a plurality of layers of a step-like pattern in which a plurality of types of layers are stacked.

For example, the stack obtained by alternately stacking insulating layers (first layers) and sacrificial layers (second layers) and the silicon layer (mask layer) on the stack are subjected to selective wet etching to etch the insulating layers, the sacrificial layers, and the mask layer with the first etching solution, the second etching solution, and the third etching solution. This treatment enables formation of the step-like pattern of insulating layers and sacrificial layers solely by wet etching.

In a semiconductor memory of a three-dimensional stacked type, a step-like pattern serving as a contact drawing portion of the conductive layers has several dozen layers. This structure also increases the cost of manufacturing the step-like pattern. When dry etching (such as RIE) is used for forming the step-like pattern, dry etching requires manufacturing cost higher than that of wet etching.

Using wet etching for forming the step-like pattern as in the present embodiment reduces the number of times of photolithography, and removes the necessity for using dry etching that requires high manufacturing cost. For this reason, the present embodiment reduces the manufacturing cost.

### [2] Other Embodiments

The above embodiment illustrates the example in which insulating layers (first layers) and sacrificial layers (second layers) are stacked and a silicon layer is used as a mask layer. The following explanation illustrates an example of using other materials as the first layers, the second layers, and the mask layer.

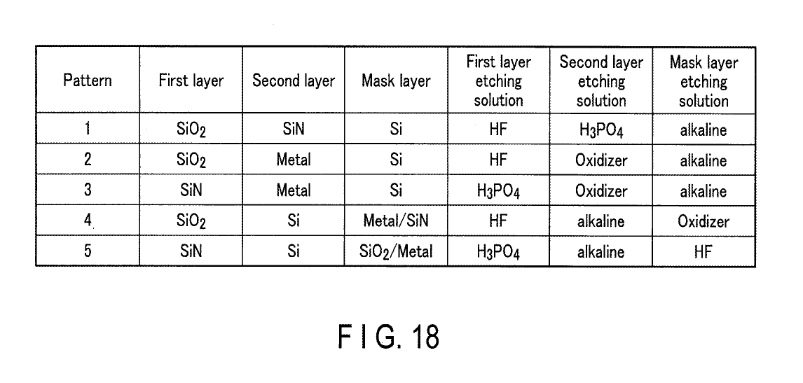

FIG. 18 illustrates relations among the first layers, the second layers, the mask layer, the first layer etching solution, the second layer etching solution, and the mask layer etching solution.

Pattern 1 illustrated in FIG. 18 illustrates the embodiment described above.

Pattern 2 illustrates an example where the first layers are silicon oxide layers, the second layers are metal layers, the mask layer is a silicon layer, the first layer etching solution is a chemical solution including hydrofluoric acid, the second layer etching solution is a chemical solution including an oxidizer, and the mask layer etching solution is a chemical solution including an alkaline aqueous solution. The metal layer is, for example, a layer including W. The oxidizer is, for example, hydrogen peroxide water or nitric acid.

Pattern 3 illustrates an example where the first layers are silicon nitride layers, the second layers are metal layers, the mask layer is a silicon layer, the first layer etching solution is hot phosphoric acid (such as a high-temperature chemical solution including H₃PO₄), the second layer etching solution is a chemical solution including an oxidizer, and the mask layer etching solution is a chemical solution including an alkaline aqueous solution. The metal layer is, for example, a layer including W.

Pattern 4 illustrates an example where the first layers are silicon oxide layers, the second layers are silicon layers, a lower portion of the mask layer is a metal layer, an upper portion of the mask layer is a silicon nitride layer, the first layer etching solution is a chemical solution including hydrofluoric acid, the second layer etching solution is a chemical solution including an alkaline aqueous solution, and the mask layer etching solution is a chemical solution including an oxidizer. The metal layer is, for example, a layer including W.

Pattern 5 illustrates an example where the first layers are silicon nitride layers, the second layers are silicon layers, a lower portion of the mask layer is a silicon oxide layer, an upper portion of the mask layer is a metal layer, the first layer etching solution is hot phosphoric acid (such as a high-temperature chemical solution including H₃PO₄), the second layer etching solution is a chemical solution including an alkaline aqueous solution, and the mask layer etching solution is a chemical solution including hydrofluoric acid. The metal layer is, for example, a layer including W.

The structures using Patterns 2 to 5 also enable formation of the first layers and the second layers in the step-like manner, like the embodiment described above.

### [3] Flow of Etching Process

The following is a detailed description of a flow of an etching process of the insulating layers (first layers), the sacrificial layers (second layers), and the mask layer in the embodiment and other embodiments.

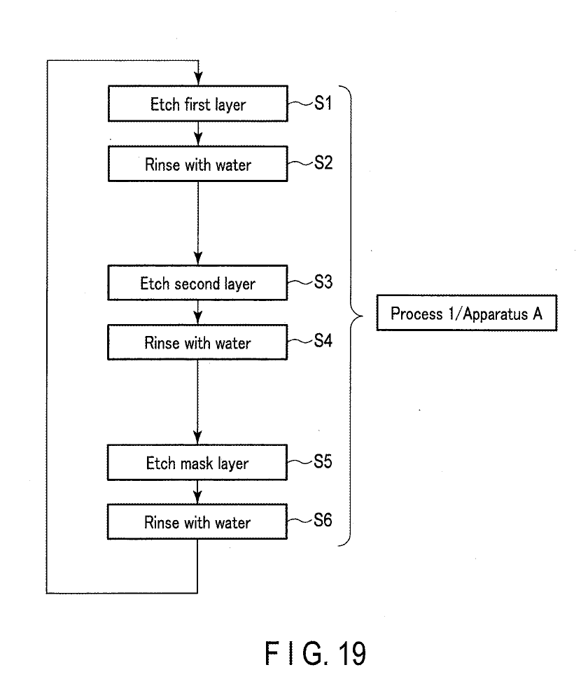

FIG. 19 is a flowchart illustrating a process of etching a wafer on which semiconductor devices are formed.

First, the first layer on the wafer is removed by wet etching using the first etching solution (S1). Thereafter, the wafer is rinsed with, for example, pure water (S2).

Next, the second layer on the wafer is removed by wet etching using the second etching solution (S3). Thereafter, the wafer is rinsed with, for example, pure water (S4).

Next, the mask layer on the wafer is removed by wet etching using the third etching solution (S5). Thereafter, the wafer is rinsed with, for example, pure water (S6). The steps from S1 to S6 are referred to as Process 1.

Thereafter, the process returns to the step S1, and Process 1 from S1 to S6 is repeated until a step-like pattern is formed. The above process is performed in the same apparatus A.

As illustrated in FIG. 19, after the water is rinsed with pure water using the same apparatus A, the process goes to the next wet etching step without drying the wafer. This process shortens the time for manufacturing the semiconductor device, and improves the manufacturing efficiency (productivity).

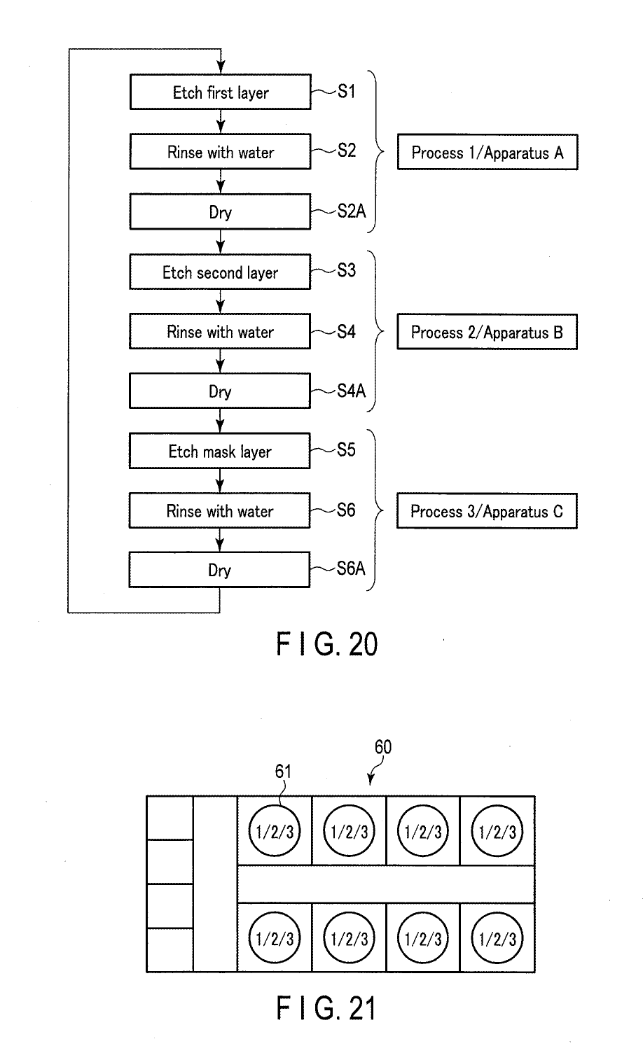

The following is an explanation of a flow of a process of etching a wafer on which semiconductor devices are formed, as a comparative example. FIG. 20 is a flowchart illustrating the process of etching a wafer as a comparative example.

As illustrated in FIG. 20, the comparative example has the structure in which the wafer is rinsed with pure water (S2, S4, and S6), and thereafter the step of drying the wafer (S2A, S4A, and S6A) is performed, in each of apparatuses A, B, and C that perform Processes 1, 2, and 3, respectively.

As illustrated in the comparative example, when the drying step to dry the wafer is performed for each of the wet etching steps with different etching solutions, the process requires three times as many drying steps as the number of stacked layers of the first layers and the second layers, and thus requires a very long manufacturing time.

To prevent deterioration in the manufacturing efficiency as described above, the present embodiment has the structure of proceeding to the subsequent etching step after the pure water rinse step is performed, without drying the wafer. This structure shortens the time for manufacturing the semiconductor device, and improves the manufacturing efficiency.

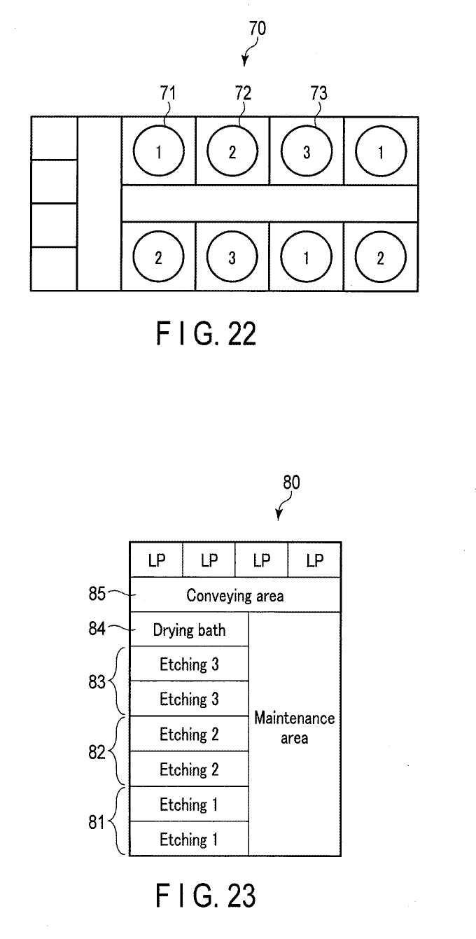

FIG. 21, FIG. 22, and FIG. 23 illustrate a structure for successively performing a wet etching process with a manufacturing apparatus without drying the wafer.

A manufacturing apparatus 60 illustrated in FIG. 21 is a single wafer apparatus, and includes a plurality of chambers 61, each of which includes a nozzle capable of supplying three types of etching solution, and a switching unit (not illustrated) to switch the etching solution supplied from the nozzle out of the three types of etching solution. The nozzle of each of the chambers 61 switches and supplies the three types of etching solution to one wafer.

A manufacturing apparatus 70 illustrated in FIG. 22 is also a single wafer apparatus, and includes a plurality of chambers including chambers 71, 72, and 73, and a moving mechanism (not illustrated) to move the wafer between the chambers. The chambers 71, 72, and 73 supply respective different etching solutions. In the manufacturing apparatus 70, the different etching solutions are supplied to the wafer in the respective chambers 71, 72, and 73. The wafer is rinsed with pure water, and moved between the chambers 71, 72, and 73 without being dried.

A manufacturing apparatus 80 illustrated in FIG. 23 is a batch apparatus. A plurality of wafers are subjected to wet etching in an etching bath 81 using the first etching solution. Thereafter, the wafers are moved to an etching bath 82, and subjected to wet etching in the etching bath 82 using the second etching solution. Thereafter, the wafers are moved to an etching bath 83, and subjected to wet etching in the etching bath 83 using the third etching solution. Then, the wafers are returned to the etching bath 81, and wet etchings in the etching baths 81, 82, and 83 are successively repeated. When the etching is finished, the wafers are moved to a drying bath 84, and dried. Thereafter, the wafers are conveyed in a conveying area 85.

An apparatus may be used with a structure in which a plurality of wafers are successively treated in the same bath. Alternatively, an apparatus may be used with a structure in which a wafer in a state of being rinsed with pure water is moved between baths.

### [4] Other Modifications

The memory string in the memory cell array is not limited to have a U shape, but may have an I shape that extends in a straight-line manner in the direction of stacking the conductive layers WL. In addition, the insulating film structure between the conductive layers WL and the channel body 20 is not limited to the ONO (Oxide/Nitride/Oxide) structure, but may be a two-layer structure formed of, for example, a charge storage layer and a gate insulating film.

The structure of a memory cell array of a three-dimensional stacked nonvolatile semiconductor memory is disclosed in, for example, U.S. patent application Ser. No. 12/407,403 filed on Mar. 19, 2009 with the title “Three-dimensional Stacked Nonvolatile Semiconductor Memory”, U.S. patent application Ser. No. 12/406,524 filed on Mar. 18, 2009 with the title “Three-dimensional Stacked Nonvolatile Semiconductor Memory”, U.S. patent application Ser. No. 13/816,799 filed on Sep. 22, 2011 with the title “Nonvolatile Semiconductor Storage Device”, and U.S. patent application Ser. No. 12/5,32,030 filed on Mar. 23, 2009 with the title “Semiconductor Memory and Method for Manufacturing the Same”. The entire contents of these patent applications are incorporated herein by reference.

As described above, the embodiments provide a method for manufacturing a semiconductor device and a semiconductor device manufacturing apparatus that enable easy formation of a step-like pattern of a plurality of layers obtained by stacking a plurality of types of layers.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
alternately stacking second layers and first layers on a substrate to form a stack;
forming a mask layer on the first layer in a surface of the stack;
removing part of the mask layer to expose part of the first layer, and foaming a protective layer in a surface layer of the mask layer;
etching the exposed first layer with a first etching solution to expose part of the second layer, after forming the protective layer;
etching the exposed second layer with a second etching solution, after etching the first layer; and
etching the mask layer with a third etching solution to further expose part of the first layer, after etching the first layer and etching the second layer.

2. The method according to claim 1, wherein an etching rate of the first etching solution for the first layers is higher than an etching rate of the first etching solution for the second layers and the mask layer.

3. The method according to claim 1, wherein an etching rate of the second etching solution for the second layers is higher than an etching rate of the second etching solution for the first layers and the mask layer.

4. The method according to claim 1, wherein an etching rate of the third etching solution for a portion of the mask layer without the protective layer is higher than an etching rate of the third etching solution for the first layers and the second layers.

5. The method according to claim 1, wherein the protective layer includes at least one of boron (B), phosphor (P), arsenic (As), aluminum (Al), and carbon (C).

6. The method according to claim 1, wherein the first layers are silicon oxide layers, the second layers are silicon nitride layers, and the mask layer is a layer including silicon.

7. The method according to claim 1, wherein the first layers are silicon oxide layers, the second layers are metal layers, and the mask layer is a layer including silicon.

8. The method according to claim 1, wherein the first layers are silicon nitride layers, the second layers are metal layers, and the mask layer is a layer including silicon.

9. The method according to claim 1, wherein the first layers are silicon oxide layers, the second layers are layers including silicon, and the mask layer is a laminated layer of a metal layer and a silicon nitride layer.

10. The method according to claim 1, wherein the first layers are silicon nitride layers, the second layers are layers including silicon, and the mask layer is a laminated layer of a silicon oxide layer and a metal layer.

11. The method according to claim 1, wherein each of the first, the second, and the third etching solutions includes at least one of hydrofluoric acid, hot phosphoric acid, an oxidizer, and an alkaline aqueous solution.

12. The method according to claim 1, wherein the oxidizer includes at least one of hydrogen peroxide water and nitric acid.

13. The method according to claim 1, wherein etching the second layer is performed without performing drying after etching the first layer, and an end portion of the mask layer is etched without performing drying after etching the second layer.

14. A semiconductor device manufacturing apparatus performing wet etching on a substrate provided with a stack and a mask layer, the stack formed by alternately stacking second layers and first layers, comprising:
a first nozzle supplying a first etching solution to etch the first layer exposed under the mask layer and expose part of the second layer;
a second nozzle supplying a second etching solution to etch the exposed second layer after etching the first layer; and
a third nozzle supplying a third etching solution to etch the mask layer and expose part of the first layer, after etching the first layer and etching the second layer.
